(19) United States
(12) Patent Application Publication
(10) Pub. No.: US 2007/0189100 A1
(43) Pub. Date: Aug. 16, 2007

(54) Semiconductor memory

(75) Inventors: Toshio Ogawa, Kawasaki (JP); Yoshihiro Takemae, Kasugai (JP); Yoshinori Okajima, Kawasaki (JP); Tetsuhiko Endo, Kawasaki (JP); Yasuro Matsuzaki, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/443,028

(22) Filed: May 31, 2006

(30) Foreign Application Priority Data
Feb. 16, 2006 (JP) 2006-039852

(51) Int. Cl. G11C 7/10; G11C 8/00

(52) U.S. Cl. 365/230.03; 365/189.05

(57) ABSTRACT

A memory cell array ARY includes a plurality of sub-arrays SARY. A data transfer unit DTU alternately accesses the sub-arrays SARY to transfer data between the sub-arrays SARY. Accordingly, it is possible to transfer data stored in one of the sub-arrays SARY to another sub-array SARY without outputting the data to a bus connected to a semiconductor memory MEM. For example, a microcontroller CNT in a system MSYS can use the bus during the data transfer since the bus is not used for the data transfer. As a result, it is possible to prevent the performance of the system MSYS from being deteriorated due to the data transfer.

### CROSS REFERENCE TO RELATED APPLICATION

This application is based upon and claims the benefit of priority from Japanese Patent Application No. 2006-039852, filed on Feb. 16, 2006, the entire contents of which are incorporated herein by reference.

### BACKGROUND OF THE INVENTION

1. Field of the Invention

The present invention relates to a semiconductor memory having a data transfer function and to a memory system having the semiconductor memory.

2. Description of the Related Art

A data read/write operation on a semiconductor memory is carried out by accessing the semiconductor memory with a microcontroller, such as a CPU. The semiconductor memory may be accessed by a DMAC (Direct Memory Access Controller) to reduce a load imposed on the microcontroller. However, when the microcontroller and the DMAC are connected to the same bus, the microcontroller cannot use the bus while the DMAC is operating, resulting in deterioration of the system performance. Accordingly, a technique has been proposed that separately provides a bus connected to the DMAC and a bus connected to the microcontroller so that a microcomputer can operate while the DMAC is operating (for example, see Japanese Unexamined Patent Application Publication No. 2000-235560).

Meanwhile, the memory capacity of the semiconductor memory is on the rise every year. Accordingly, a single semiconductor memory chip can now replace a plurality of semiconductor memory chips mounted in a system. In this case, data transfer for the microcontroller needs to be performed between memory cell arrays in the single semiconductor memory chip rather than between a plurality of semiconductor memory chips.

Generally, a specific specification is required for the data transfer between a plurality of microcontrollers. For instance, a dedicated signal line is provided between the microcontrollers. Further, it is difficult to directly transfer data when the microcontrollers are different from each other in their operating frequencies and/or in their data bit widths. In this case, the data is transferred through a semiconductor memory acting as a buffer.

When data used in the microcontroller is transferred between memory cell arrays in the semiconductor memory, the semiconductor memory is accessed by the microcontroller or the DMAC. In this case, a bus connected to the semiconductor memory cannot be used for other access while data is being transferred, leading to inefficient use of the bus. As a result, the system performance degrades.

When data is transferred between microcontrollers using the semiconductor memory as a buffer, data transfer specifications need to be determined for each system. In this case, since data transfer efficiencies are different in each system, performances of some of the systems may be degraded. In order to standardize the transfer specifications and to prevent the system performance from deteriorating, a control circuit for transferring data between the microcontrollers needs to be implemented on a semiconductor memory commonly used for a plurality of microcontrollers. However, such a control circuit has not been proposed until now.

### SUMMARY OF THE INVENTION

An object of the invention is to prevent system performance from being deteriorated due to data transfer.

According to a first aspect of the present invention, a memory cell array includes a plurality of sub-arrays. A data transfer unit alternately accesses the sub-arrays to transfer data between the sub-arrays. Accordingly, data stored in one of the sub-arrays can be transferred to another sub-array without outputting the data to a bus connected to a semiconductor memory. Thus, for example, a microcontroller in a system can use the bus during the data transfer since the bus is not used for the data transfer. As a result, it is possible to prevent the system performance from being deteriorated due to the data transfer.

For example, the data transfer unit initiates data transfer in response only to a transfer request of a master controller. The data transfer unit does not accept a transfer request from a sub-controller connected to the semiconductor memory. Accordingly, it is possible to prevent the sub-controller from performing incorrect data transfer. In other words, it is possible to improve the reliability of the system on which the semiconductor memory is mounted.

In a preferred example of the first aspect of the present invention, a transfer source address of and a transfer destination address of data transferred by a data transfer unit are stored in a transfer register. Since data transfer can be carried out by a simple setup, it is possible to minimize a bus cycle required for a controller accessing a semiconductor memory to perform the data transfer. Accordingly, it is possible to prevent the system performance from being deteriorated due to the data transfer.

In a preferred example of the first aspect of the present invention, an access right of a controller connected to a semiconductor memory to a sub-array is set by an access right register. For example, by setting one sub-array as write prohibition and setting another sub-array as read/write permission, these sub-arrays can be accessed as ROM and RAM, respectively. In other words, a single semiconductor memory can be accessed as different types of semiconductor memory. As a result, a plurality of semiconductor memory chips mounted on the system can be replaced with a single semiconductor memory chip.

In a preferred example of the first aspect of the present invention, an access right of a data transfer unit to a sub-array is set by an access right register. For example, when there is a sub-array in which data update is prohibited, it is possible to prevent the data from being updated by preventing the data transfer unit from accessing the sub-array. Accordingly, it is possible to improve the reliability of the system on which the semiconductor memory is mounted.

In a preferred example of the first aspect of the present invention, a data transfer unit is formed on a field programmable unit in which a logic is programmable. A nonvolatile program area stores a program for configuring the logic of the field programmable unit.

Accordingly, it is possible to change an operation specification of the data transfer unit within the system according to the system specification.

In a preferred example of the first aspect of the present invention, each of two sub-arrays has an area for storing data and an area for storing an error correction code of data. Systems of the error correction codes stored in the two sub-arrays are different from each other. Accordingly, the two sub-arrays can be accessed as two semiconductor memories having different error correction code systems. In other words, it is possible to replace a plurality of semiconductor memory chips mounted on the system with a single semiconductor memory chip.

In a preferred example of the first aspect of the present invention, an error correction code generation unit generates an error correction code according to each data storage destination. The controller accessing the semiconductor memory has to write only the data into the semiconductor memory without generating the error correction code. Accordingly, it is possible to simplify the process of the controller and to reduce the amount of data to be written into the semiconductor memory. As a result, it is possible to prevent the system performance from being deteriorated due to the data transfer.

For example, when data is transferred by the data transfer unit from one sub-array to another sub-array, a code conversion unit of the error correction code generation unit converts an error correction code read from a sub-array of a transfer source to an error correction code corresponding to a sub-array of a transfer destination. Thus, it is possible to automatically convert the error correction code upon the data transfer without increasing a load of on the controller accessing the semiconductor memory.

In a second aspect of the present invention, a memory system includes a semiconductor memory having a memory cell array, a plurality of controllers accessing the semiconductor memory, and data lines connecting the semiconductor memory and the controllers. A data transfer unit of the semiconductor memory receives data outputted from one of the controllers, and outputs the data to another one of the controllers. Thus, even though operation specifications of the controllers are different from each other, it is possible to transfer data between the controllers through the semiconductor memory. More specifically, for example, even when data bit widths of the controllers are different from each other, it is possible to transfer data between the controllers. Alternatively, even when operation frequencies of the controllers are different from each other, it is possible to transfer data between the controllers.

For example, the data transfer unit has a flag indicating an access state of the controller to the semiconductor memory. Thus, it is possible to prevent conflict of access of the controllers. The data transfer unit outputs a signal indicating an access state of the controller to the semiconductor memory. The controller does not need to access the semiconductor memory to confirm the access state. Since the access frequency of semiconductor memory decreases, it is possible to prevent the performance of the memory system from being deteriorated. In addition, for example, the data transfer unit outputs a transfer clock that is a synchronous signal for outputting received data to another controller. Thus, each controller can receive the data without accessing the semiconductor memory. Since the access frequency of semiconductor memory decreases, it is possible to prevent the performance of the memory system from being deteriorated.

Alternatively, by forming the data transfer unit in the field programmable unit and storing a program for configuring a logic of the field programmable unit in a nonvolatile program area, it is possible to change operation specification of the data transfer unit within the system to be suited to the system specification.

In a preferred example of the second aspect of the present invention, a memory cell array is partitioned into a normal memory area and a buffer area. The normal memory area is accessed by each controller. The buffer area temporarily stores data received by the data transfer unit. By partitioning the memory cell array into the normal memory area used for normal access and the buffer area, it is possible to prevent the normal memory area from being incorrectly updated even though there is a large amount of transferred data. As a result, it is possible to improve the reliability of the memory system.

In a preferred example of the second aspect of the present invention, one or more of the controllers are a master controller and the rest are sub-controllers. The data lines are independently provided on the respective controllers. The data transfer unit outputs data received from the master controller to the sub-controllers. In other words, it is possible to simultaneously output the data to the sub-controllers by functioning the semiconductor memory as a buffer. For example, by forming, in the data transfer unit, a transfer destination register for storing transfer destination information sent from the master controller, the data transfer unit can easily recognize the sub-controller to which the data is output.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a block diagram of a first embodiment according to the invention;

FIG. 2 is an explanatory diagram showing a memory map of a memory cell array shown in FIG. 1;

FIG. 3 is a block diagram of a second embodiment according to the invention;

FIG. 4 is a block diagram of a third embodiment according to the invention;

FIG. 5 is a block diagram of a fourth embodiment according to the invention;

FIG. 6 is a block diagram of a fifth embodiment according to the invention;

FIG. 7 is a flow chart of data transfer operation of a memory system shown in FIG. 6;

FIG. 8 is a block diagram of a sixth embodiment according to the invention;

FIG. 9 is a block diagram of a seventh embodiment according to the invention;

FIG. 10 is a block diagram of an eighth embodiment according to the invention;

FIG. 11 is a block diagram of a ninth embodiment according to the invention;

FIG. 12 is a block diagram of a tenth embodiment according to the invention;

FIG. 13 is a block diagram of an eleventh embodiment according to the invention;

FIG. 14 is a block diagram of a twelfth embodiment according to the invention; and

FIG. 15 is a block diagram of a thirteenth embodiment according to the invention.

### DESCRIPTION OF THE PREFERRED EMBODIMENTS

Preferred embodiments of the invention will be described with reference to the accompanying drawings. In the drawings, a double circle indicates an external terminal, and a signal line indicated by a thick line represents a plurality of signal lines. In addition, a part of a block connected to the thick line includes a plurality of circuits. A signal supplied through the external terminal is denoted by the same symbol as the name of the terminal. In addition, a signal line to which a signal is supplied is denoted by the same symbol as the name of the signal.

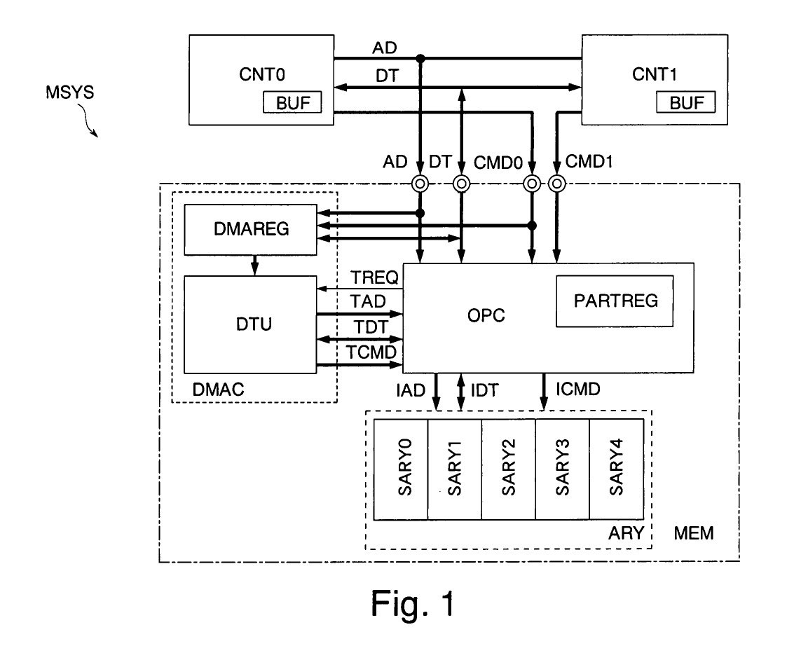

FIG. 1 is a block diagram of a first embodiment according to the invention. In the present embodiment, a semiconductor memory MEM is formed as a nonvolatile semiconductor memory, such as FRAM (Ferroelectric RAM) or the like, on a silicon substrate by a CMOS process.

The semiconductor memory MEM includes a direct memory access controller DMAC, an operation control circuit OPC, and a memory cell array ARY. Since the memory MEM is accessed by a plurality of master controllers CNT (CNT0 and CNT1), it has an address terminal AD and a data terminal DT which are common to the master controllers CNT0 and CNT1, and command terminals CMD1 and CMD2 corresponding to the controllers CNT0 and CNT1.

Each of the controllers CNT0 and CNT1 is a microcontroller such as a CPU, and has a buffer BUF for temporarily storing data. A memory system MSYS includes the memory MEM, the controllers CNTO and CNT1, external buses (AD, DT, and CMD0 and CMD1) for connecting the memory MEM to the controllers CNT0 and CNT1.

The controller CNT0 accesses the memory MEM as DRAM. The controller CNT1 accesses the memory MEM as NOR-type flash memory (FLASH). Thus, the operation control circuit OPC has a function of converting DRAM interface (access specification of DRAM) and FLASH interface (access specification of FLASH) into FRAM interface (access specification of FRAM).

The DMAC includes a transfer register DMAREG, which can be updated from the outside, and a data transfer unit DTU. The transfer register DMAREG is assigned, for example, to an I/O space of the controller CNT0 (memory map I/O), and can be read and written only by the controller CNT0. When the controller CNT0 reads and writes the transfer register DMAREG, it supplies the command CMD0 (read command or write command), together with the address AD assigned to the transfer register DMAREG, to the memory MEM.

The transfer register DMAREG includes a source address area, which stores an initial address (a transfer source address) of a memory area for storing data to be transferred, a destination address area, which stores an initial address (a transfer destination address) of a memory area to which data is transferred, and a transfer byte area for storing the number of transferred data (for example, the number of bytes). Since data transfer can be carried out by simple register setup, it is possible to minimize a bus cycle required for the controller CNT0 to transfer the data. Accordingly, it is possible to prevent the performance of the memory system MSYS from being deteriorated due to the data transfer.

The data transfer unit DTU initiates a data transfer operation in response to a transfer request command CMD0 (TREQ) from the controller CNT0. The controller CNT0 operates as a master controller which supplies a transfer request to the DMAC. The controller CNT1 operates as a sub-controller which cannot supply the transfer request to the DMAC, thereby preventing data from being incorrectly transferred by the controller CNT1. Accordingly, it is possible to improve the reliability of the memory system MSYS.

In response to the transfer request, the data transfer unit DTU reads a source address, a destination address, and the number of data transferred from the transfer register DMAREG. The date transfer unit DTU sequentially outputs an address TAD and a command TCMD (read command or write command) to the operation control circuit OPC to alternately carry out the read operation to the source address and the write operation to the destination address, i.e., to alternately access the following sub-array SARY. At this time, the address TAD sequentially increases as much as the number of transferred data.

The operation control circuit OPC decodes commands CMD0-1 (external access requests) supplied from the outside of the memory MEM through the command terminals CMD0 and CMD1, and a command TCMD (DMA transfer request) supplied from the DMAC, outputs an access signal (internal address IAD, internal command ICMD) for accessing the memory cell array ARY, and inputs or outputs internal data IDT. In addition, the operation control circuit OPC includes a partition register PARTREG to partition the memory cell array ARY into a plurality of sub-arrays SARY (SARY0 to SARY4 in this example). The partition register PARTREG can be updated from the outside.

The partition register PARTREG is assigned, for example, to an I/O space of the controller CNT0 (memory map I/O). The partition register PARTREG includes, for example, an area for storing the number of sub-arrays SARY partitioned, an initial address and end address of each of the sub-arrays SARY, and an access right of each of the sub-arrays SARY.

The term “access right” implies read permission and write permission by the controllers CNT0 and CNT01 and write prohibition by the DMAC. The read permission and write permission can be set for each of the controllers CNT0 and CNT1. The partition register PARTREG acts as an access right register for setting the access right of the sub-arrays SARY0 to SARY4.

In addition, the operation control circuit OPC has an arbiter (not shown) for determining an access order of the controllers CNT0 and CNT1 when access conflict of the controllers CNT0 and CNT1 occurs. When conflict of the commands CMD0 and CMD1 occurs, the arbiter determines which command should be first carried out according to a predetermined priority. In the present embodiment, the controller CNT1 fetches and operates data stored in the memory cell array ARY as a program. Accordingly, the command CMD1 is set to have priority over the command CMD0.

The memory cell array ARY has the sub-arrays SARY0 to SARY4 partitioned by the partition register PRTREG, an address decoder, and word lines, bit lines and sense amplifiers for accessing memory cells. Each of the sub-arrays SARY0 to SARY4 has memory cells (nonvolatile memory cells) of FRAM. The memory cell array ARY carries out read operation or write operation according to the internal command ICMD.

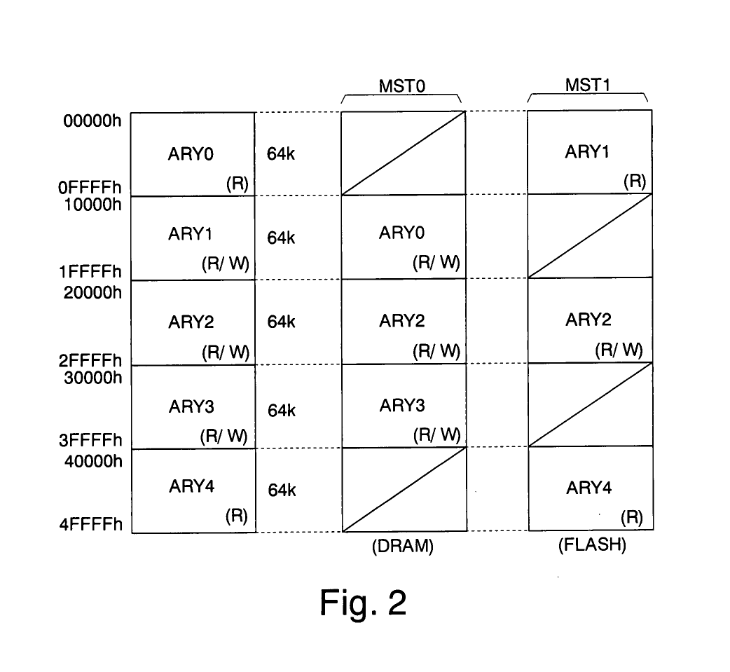

FIG. 2 is a memory map of the memory cell array ARY shown in FIG. 1. A memory map of the I/O space is not shown. The memory cell array ARY has a memory area of 320 k words partitioned into the sub-arrays SARY0 to SARY4. Each of the sub-arrays SARY0 to SARY4 has a memory area of 64 k words. The size of the memory area of the sub-arrays SARY0 to SARY4 can be changed by the partition register PARTREG.

Since the sub-array SARY0 is a ROM area, it can be only read (R) by the controller CNT1 and cannot be accessed by the controller CNT0. The sub-array SARY0 stores a program executed by the controller CNT1. Write access of the DMAC to the sub-array SARY0 is prohibited to prevent the program being updated. The prohibition can be set by the partition register PRTREG. Accordingly, since data cannot be updated by an incorrect DMA operation, it is possible to improve the reliability of the memory system MSYS.

The sub-array SARY0I is readable and writable (R/W) by the controller CNT0 and cannot be accessed by the controller CNT1. The sub-array SARY2 is readable and writable (R/W) by the controllers CNT0 and CNT1. The sub-array SARY3 is readable and writable (R/W) by the controller CNT0 and cannot be accessed by the controller CNT1. The sub-array SARY4 is a ROM area, and can be only read (R) by the controller CNT1 but cannot be accessed by the controller CNT0.

In the present embodiment, each of the sub-arrays SARY0 to SARY4 can be set to be shared by a plurality of controllers CNT or excluded from a predetermined controller CNT. That is, it is possible to set the access right (read-write permission, read permission, read prohibition, write prohibition, etc.) of each of the sub-arrays SARY0 to SARY4.

As described above, the controller CNT0 accesses the sub-arrays SARY0 to SARY3 as DRAM. The controller CNT1 accesses the sub-arrays SARY0 and SARY4 as FLASH. That is, a single memory MEM can be used instead of the conventional DRAM chip and FLASH chip. In other words, the conventional semiconductor memories (DRAM, FLASH) provided for the respective controllers CNT0 and CNT1 can be replaced by a single semiconductor memory MEM, resulting in reduced system costs.

The memory system MSYS stores data stored in the sub-array SARY3 accessed as DRAM, for example, upon power-off to the sub-array SARY4 accessed as FLASH. Thus, the memory system MSYS can realize the power-off operation of the conventional semiconductor memory chips (DRAM and FLASH) by using a single semiconductor memory MEM. In addition, since the DRAM and FLASH functions can be realized with a single chip, it is possible to easily realize a common area (for example, sub-array SARY2) that can be accessed as both DRAM and FLASH.

According to the first embodiment, it is possible to transfer data that is stored in the sub-array SARY and is used by the controllers CNT0 and CNT1 without outputting the data to the external data line DT. The controllers CNT0 and CNT1 can use external buses AD and DT during the data transfer. As a result, it is possible to prevent the performance of the memory system MSYS from being deteriorated due to the data transfer.

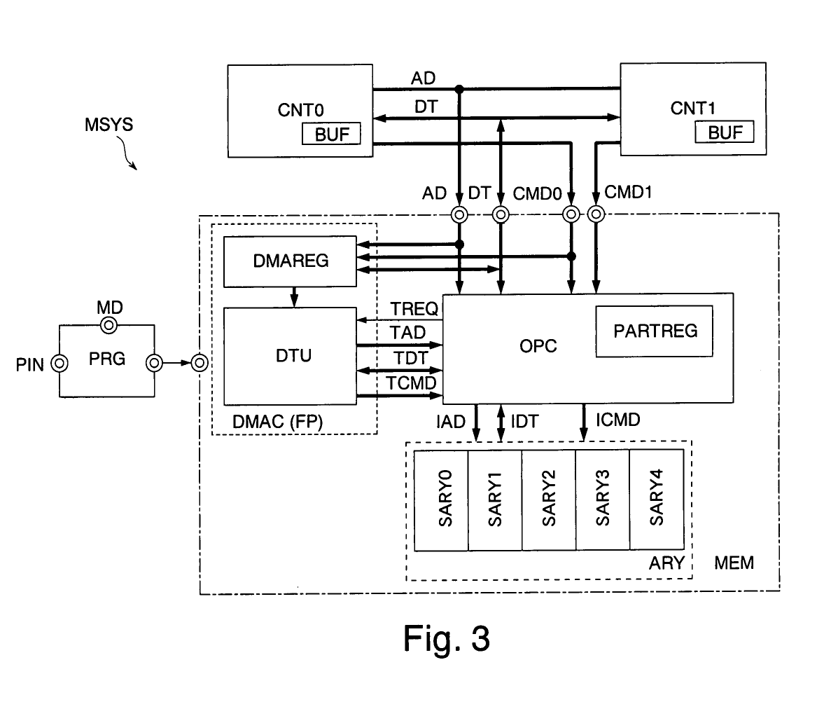

FIG. 3 illustrates a second embodiment of the invention. The same elements as those of the first embodiment are denoted by the same reference symbols and a detailed description thereof will thus be omitted herein. In the present embodiment, a DMAC is formed on a field programmable unit FP. Other configuration is the same as that of the first embodiment.

The field programmable unit FP includes, for example, a plurality of logic elements, and a plurality of switching elements for connecting the logic elements. The switching element is formed by using a volatile memory cell. The switching element of the field programmable unit FP is programmed by a program loaded from a program memory unit PRG. A hardware function is realized by the program.

The program memory unit PRG is formed by using nonvolatile memory cells such as FRAM. The program memory unit PRG stores a program supplied from the outside through a program input terminal PIN. In the present embodiment, the program memory unit PRG can store two types of programs. For example, the program memory unit PRG outputs one of the programs to the field programmable unit FP to configure a DMAC according to a logic level of a mode signal MD supplied from the outside through a mode terminal MD. The program is transferred to the field programmable unit FP, for example, through a dedicated port such as a JTAG (joint Test Action Group) standard port and an I²C (Inter Integrated Circuit) standard port.

The second embodiment can achieve the same effect as that of the above-mentioned first embodiment. In this embodiment, it is possible to change the DMAC function after manufacturing the semiconductor memory MEM by forming the DMAC on the field programmable unit FP. It is possible to change the operation specification of the DMAC on the memory system MSYS according to the specification of the memory system MSYS.

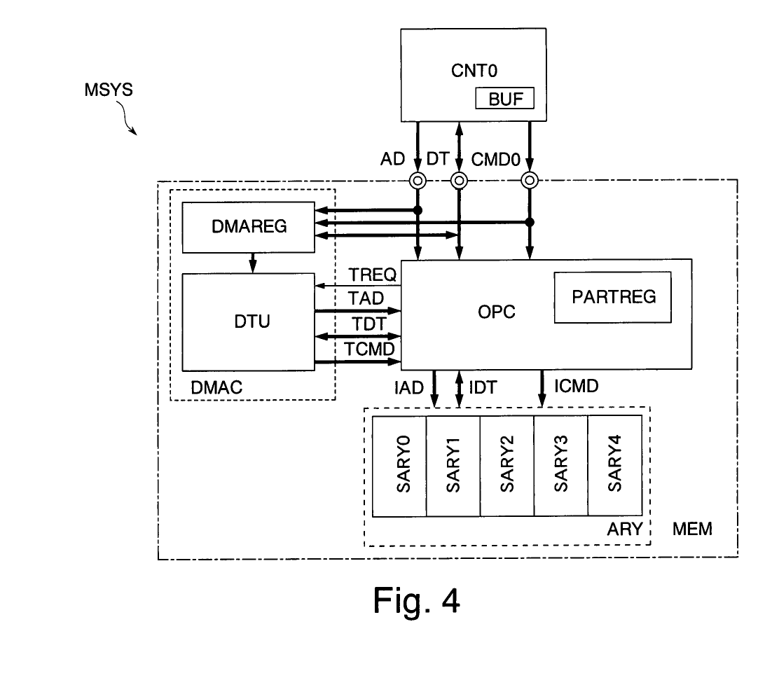

FIG. 4 illustrates a third embodiment of the invention. The same elements as those of the first embodiment are denoted by the same reference symbols and a detailed description thereof will thus be omitted herein. In the present embodiment, the semiconductor memory MEM includes terminals AD, DT, and CMD0 for connection with one master controller CNT0. Thus, the operation control circuit OPC does not include an arbiter. Other configuration is the same as that of the first embodiment. The third embodiment can achieve the same effect as the above-mentioned first embodiment.

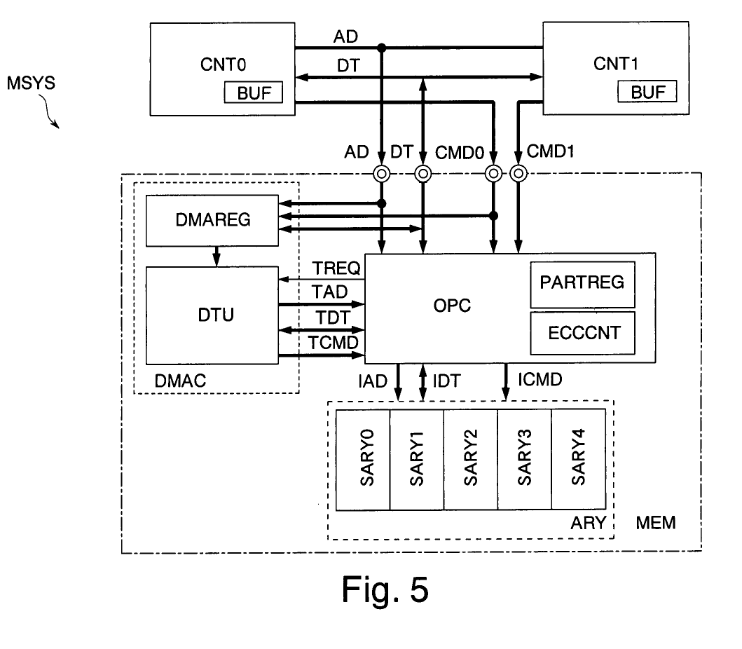

FIG. 5 illustrates a fourth embodiment of the invention. The same elements as those of the first embodiment are denoted by the same reference symbols and a detailed description thereof will thus be omitted herein. In the present embodiment, the operation control circuit OPC includes an error control circuit ECCCNT. Other configuration is almost the same as that of the first embodiment except that the memory cell array ARY stores an error correction code together with data.

In the present embodiment, the sub-arrays SARY1 to SARY3 are accessed as DRAM by the controller CNT0. The sub-arrays SARY0 and SARY4 are accessed as FLASH by the controller CNT1. In addition, the sub-arrays SARY1 to SARY3 have an area for storing data, and an area for storing an error correction code for DRAM. The sub-arrays SARY0 and SARY4 have an area for storing data and an area for storing an error correction code for FLASH.

For example, the error correction code for DRAM has one byte (8 bits) with respect to data having eight bytes (64 bits). The error correction code for FLASH has sixteen bytes with respect to data having 512 bytes.

The error control circuit ECCCNT includes error correction code generation units, which generate error correction codes, respectively, by using data written in the sub-arrays serving as DRAM and data written in the sub-arrays serving as FLASH, and error correcting units, which correct errors by using corresponding error correction codes when the errors are detected from read data. The error control circuit ECCCNT includes a code conversion unit (not shown) that converts an error correction code for DRAM to an error correction code for FLASH when data is transferred from a DRAM area to a FLASH area by the DMAC. The code conversion unit converts an error correction code for FLASH to an error correction code for DRAM when data is transferred from the FLASH area to the DRAM area by the DMAC.

In more detail, the error control circuit ECCCNT corrects data read from the sub-arrays serving as DRAM and generates an error correction code for FLASH. Next, the operation control circuit OPC writes data and the error correction codes for FLASH into the FLASH area. When DMA transfer is carried out from the FLASH area to the DRAM area, the data is corrected and the error correction code for FLASH is converted to the error correction code for DRAM.

In the present embodiment, since an error correction process is performed in the memory MEM, the controllers CNT0 and CNT1 do not generate an error correction code and has only to write data into the memory MEM. In addition, the controllers CNT0 and CNT1 do not need to correct an error. Accordingly, it is possible to conveniently process the controllers CNT0 and CNT1 and to reduce the number of data to be written into the memory MEM. In addition, it is possible to automatically convert the error correction code in the memory MEM. As a result, it is possible to reduce the usage frequency of the external bus upon accessing the memory MEM, and to prevent the performance of system SYS from being deteriorated due to the data transfer process including the error correction process.

The fourth embodiment can achieve the same effect as that of the above-mentioned first embodiment. Further, in the present embodiment, it is possible to access the sub-arrays SARY1 to SARY3 and the sub-arrays SARY0 and SARY4 as DRAM and FLASH that are different from each other in the error correction code system. That is, it is possible to replace a plurality of semiconductor memory chips with a single semiconductor memory chip MEM.

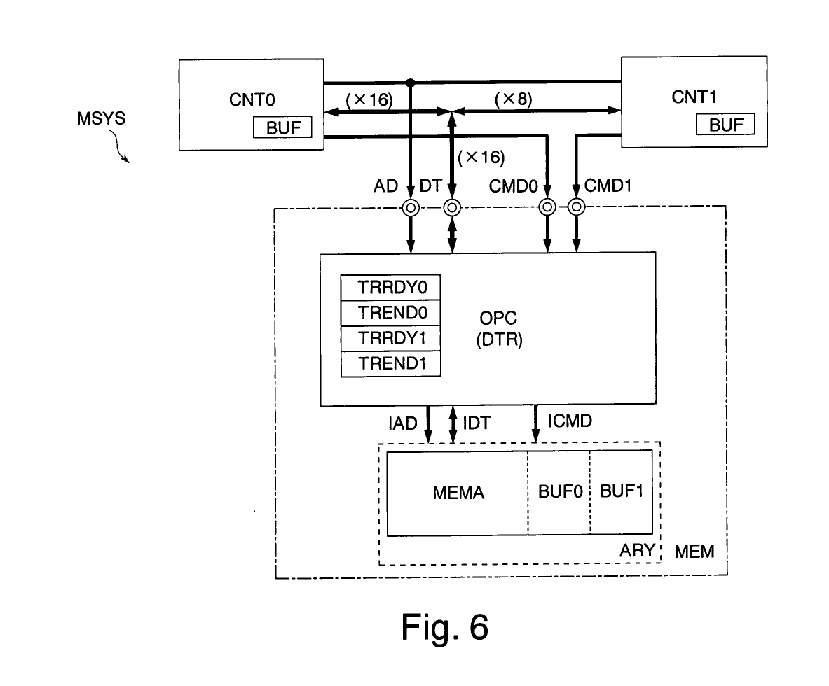

FIG. 6 illustrates a fifth embodiment of the invention. In the present embodiment, the semiconductor memory MEM is formed as a nonvolatile semiconductor memory, such as FRAM (Ferroelectric RAM) or the like, on a silicon substrate by a CM0S process.

The memory MEM includes an operation control circuit OPC and a memory cell array ARY. Since the memory MEM is accessed by a plurality of master controllers CNT (CNT0 and CNT1), it has an address terminal AD and a data terminal DT, which are common to the master controllers CNT0 and CNT1, and command terminals CMD0 and CMD1 corresponding to the controllers CNT0 and CNT1. Each of the controllers CNT0 and CNT1 is a microcontroller such as a CPU. The memory system MSYS includes the memory MEM, the controllers CNT0 and CNT1, and the external buses (AD and DT and the CMD0 and CMD1) that connects the memory MEM and the controllers CNT0 and CNT1.

The data line DT of the controller CNT0 has a width of 16 bits, and the data line of the controller CNT1 has a width of 8 bits. Thus, the data terminal of the controller CNT1 is connected to lower eight bits of the data line DT of the external bus.

The memory cell array ARY has a normal memory area MEMA and buffer areas BUF0 and BUF1. The normal memory area MEMA is a memory area for storing data read and written by the controllers CNT0 and CNT1. The buffer area BUF0 temporarily stores data transferred from the controller CNT0 to the controller CNT1. The buffer area BUF1 temporarily stores data transferred from the controller CNT1 to the controller CNT0. By differentiating the normal memory area MEMA used in normal access from the buffer areas BUF0 and BUF1 used for storing data transferred between the controllers CNT0 and CNT1, it is possible to prevent the normal memory area MEMA from being incorrectly updated even though there is a large amount of transferred data DT. Accordingly, it is possible to improve the reliability of the memory system MSYS.

In a normal memory operation, the operation control circuit OPC decodes the commands CMD0-1 (external access requests) supplied from the outside of the memory MEM through the command terminals CMD0 and CMD1, outputs access signals (an internal address IAD, an internal command ICMD) for accessing the memory cell array ARY, and inputs or outputs the internal data IDT. For example, the operation control circuit OPC accesses the memory cell array ARY in 16 bit units.

In the present embodiment, the data lines DT of the controllers CNT0 and CNT1 connected to the memory MEM have different bus widths. During a write operation by the controller CNT0, the operation control circuit OPC outputs the address AD and the data DT supplied from the controller CNT0 to the memory cell array ARY as the internal address IAD and the internal data IDT. During a read operation by the controller CNT0, the operation control circuit OPC outputs the address AD supplied from the controller CNT0 to the memory cell array ARY as the internal address IAD, and outputs the internal data IDT (16 bits) read from the memory cell array ARY to the controller CNT0 as the data DT.

Meanwhile, during the write operation by the controller CNT1, when the operation control circuit OPC receives even-numbered address AD and data DT (8 bits) from the controller CNT1, it outputs the address AD excluding the lowest bit as the internal address IAD, and outputs the data DT as the internal data IDT of the lower eight bits. Similarly, when the operation control circuit OPC receives odd-numbered address AD and data DT (8 bits) from the controller CNT1, it outputs the address AD excluding the lowest bit as the internal address IAD, and outputs the data DT as the internal data IDT of upper eight bits.

During the read operation by the controller CNT1, when the operation control circuit OPC receives even-numbered address AD from the controller CNT1, it outputs the address AD excluding 8 bits the lowest bit as the internal address IAD. The operation control circuit OPC selects 8 bits of the internal data IDT (16 bits) read from the memory cell array ARY according to the lowest bit of the address AD, and outputs the selected internal data IDT to the controller CNT1 as the data DT.

The operation control circuit OPC has an address conversion function that deletes the lowest bit of the address AD in the access by the controller CNT1. The lowest bit of the address AD is used to determine the upper byte and lower byte of data.

The operation control circuit OPC has the function of data transfer unit DTU to use the memory cell array ARY as a buffer when data is transferred between the controllers CNT0 and CNT1. Thus, the operation control circuit OPC has transfer ready flags TRRDY0 and TRRDY1 and transfer end flags TREND0 and TREND1 indicating the access state of the memory MEM.

The transfer ready flag TRRDY0 and the transfer end flag TREND0 are assigned, for example, to the I/O space (memory map I/O). The transfer ready flag TRRDY0 and the transfer end flag TREND0 can be written by the controller CNT0 and read out by the controllers CNT0 and CNT1.

The transfer ready flag TRRDY1 and the transfer end flag TREND1 are assigned, for example, to the I/O space (memory map I/O). The transfer ready flag TRRDY1 and the transfer end flag TREND1 can be written by the controller CNT1 and read out by the controllers CNT0 and CNT1.

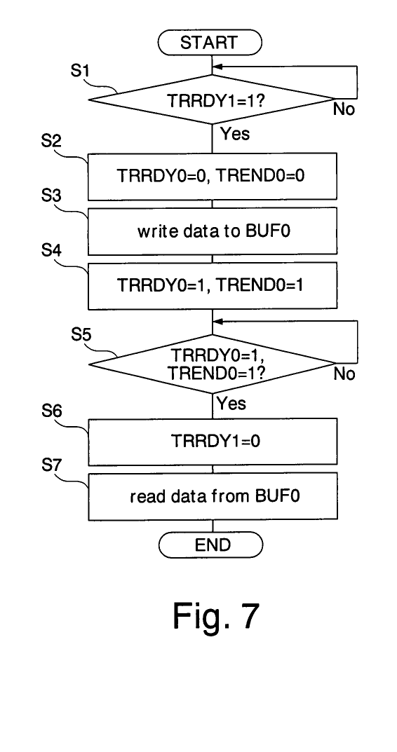

The transfer ready flags TRRDY0 and TRRDY1 are reset to “0” when the controllers CNT0 and CNT1 access the memory MEM, and are set to “1” when the controllers CNT0 and CNT1 do not access the memory MEM. The transfer end flags TREND0 and TREND1 are set to“1” when data transfer (write) from the controllers CNT0 and CNT1 to the memory MEM is completed or when data transfer (read) from the memory MEM to the controllers CNT0 and CNT1 is completed. Otherwise, the transfer end flags TREND0 and TREND1 are reset to “0” The data transfer will be described below in detail with reference to FIG. 7.

FIG. 7 illustrates the data transfer operation of the memory system MSYS shown in FIG. 6. In this example, the data DT is transferred from the controller CNT0 through the memory MEM to the controller CNT1. The process shown in FIG. 7 is carried out by the controllers CNT0 and CNT1 and the operation control circuit OPC.

In step S1, the controller CNT0 reads “1” from the transfer ready flag TRRDY1, such that it confirms that the memory MEM is not accessed bythe controller CNT1. In step S2, the controller CNT0 resets the transfer ready flag TRRDY0 and the transfer end flag TREND0 to “0” to write data transferred to the controller CNT1 into the buffer area BUF0.

In step S3, the controller CNT0 accesses the memory MEM to write the data into the buffer area BUF0. In step S4, the controller CNT0 writes the data into the buffer area BUF0 and sets the transfer ready flag TRRDY0 and the transfer end flag TREND0 to “1”.

In step S5, the controller CNT1 reads “1” from the transfer ready flag TRRDY0, such that it confirms that the memory MEM is not accessed by the controller CNT0. In addition, the controller CNT1 reads “1” from the transfer end flag TREND0, such that it confirms that data to be transferred from the controller CNT0 is stored in the buffer area BUF0.

In step S6, the controller CNT1 resets the transfer ready flag TRRDY1 to “0” to read the data from the buffer area BUF0. In step S7, the controller CNT1 reads the data from the buffer area BUF0 and sets the transfer ready flag TRRDY1 to “1”. The data transfer from the controller CNT0 to the controller CNT1 is completed.

In this example, the data DT is transferred from the controller CNT0 to the controller CNT1. Thus, the transfer end flag TREND1 indicating that the transfer from the controller CNT1 is completed is always reset to “0”. Although not shown, the data transfer operation from the controller CNT1 to the controller CNT0 is indicated by a flow chart in which the numbers (0 and 1) of the controllers CNT0 and CNT1 and the flags TRRDY0, TRRDY1, TREND0, and TREND1 in the drawing are switched.

In the fifth embodiment, even though the controllers CNT0 and CNT1 are different in bit width of the data DT from each other and the data DT cannot be directly transferred between the controllers CNT0 and CNT1, it is possible to transfer the data DT between the controllers CNT0 and CNT1 by functioning as the semiconductor memory MEM as a buffer. In addition, each of the controllers CNT0 and CNT1 can identify the access state of the memory MEM by the flags TRRDY0, TRRDY1, TREND0, and TREND1. Accordingly, it is possible to prevent conflict of accesses of the controllers CNT0 and CNT1.

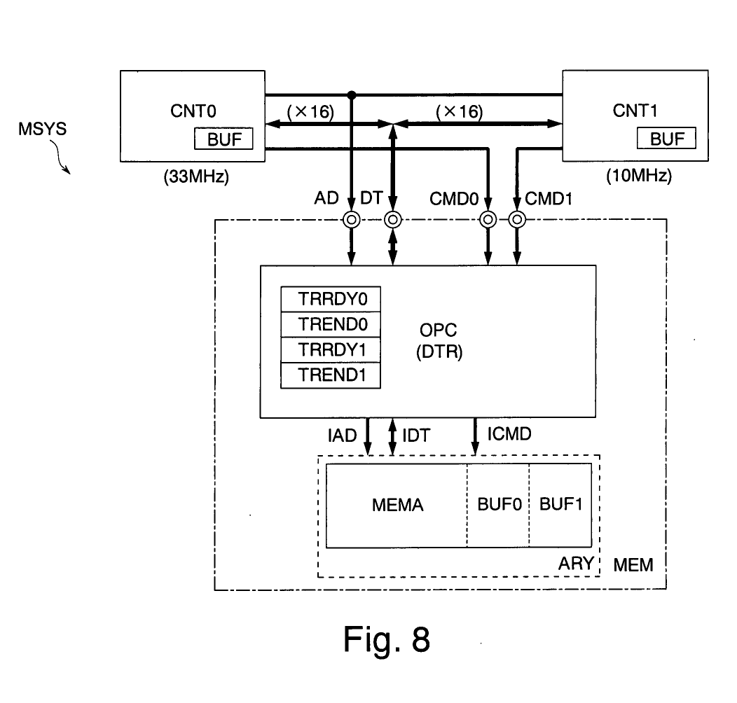

FIG. 8 illustrates a sixth embodiment of the invention. The same elements as those of the fifth embodiment are denoted by the same symbols and a detailed description thereof will thus be omitted herein. In the present embodiment, the data lines DT of the controllers CNT0 and CNT1 have a width of 16 bits. Thus, the operation control circuit OPC (data transfer unit DTU) does not have the address conversion function of the fifth embodiment. The controllers CNT0 and CNT1 have operating frequencies of 33 MHz and 10 MHz, respectively. Other configuration is the same as that of the fifth embodiment.

The sixth embodiment can achieve the same effect as that of the above-mentioned fifth embodiment. In the present embodiment, even though the controllers CNT0 and CNT1 have different operating frequencies from each other and the data DT cannot be directly transferred between the controllers CNT0 and CNT1, it is possible to transfer the data DT between the controllers CNT0 and CNT1 by functioning as the semiconductor memory MEM as a buffer.

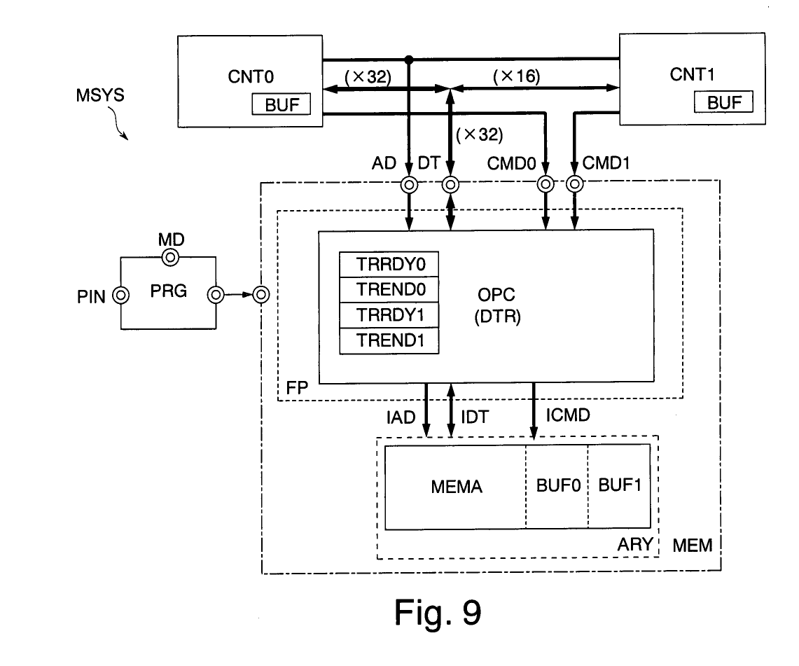

FIG. 9 illustrates a seventh embodiment of the invention. The same elements as those of the second and fifth elements are denoted by the same symbols and a detailed description thereof will thus be omitted herein. In the present embodiment, the operation control circuit OPC (data transfer unit DTU) is formed on the field programmable unit FP. Other configuration is the same as that of the fifth embodiment. The seventh embodiment can achieve the same effect as that of the above-mentioned second and fifth embodiments.

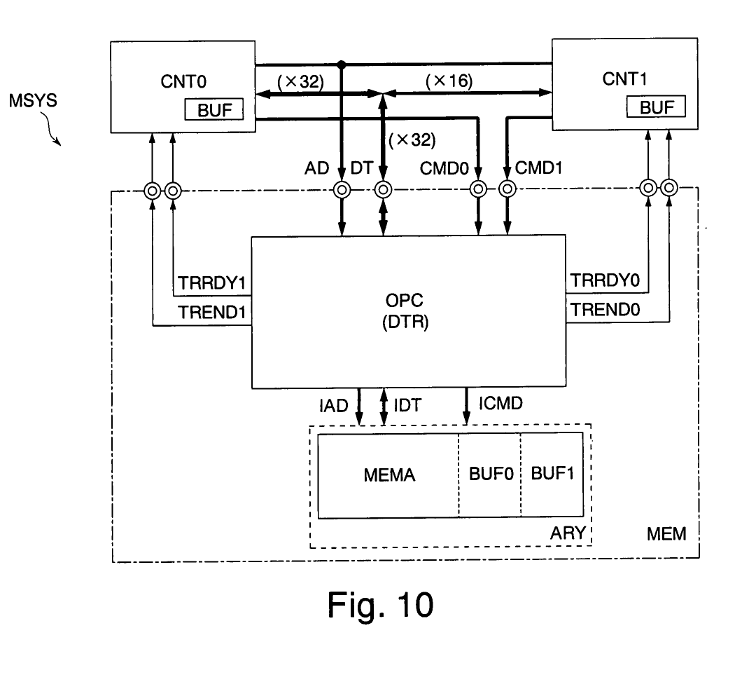

FIG. 10 illustrates an eighth embodiment of the invention. The same elements as those of the fifth embodiments are denoted by the same symbols and a detailed description thereof will thus be omitted herein. In the present embodiment, the operation control circuit OPC (data transfer unit DTU) does not include the flags TRRDY0, TRRDY1, TREND0, and TREND1 of the fifth embodiment. The operation control circuit OPC outputs the transfer ready signal TRRDY1 and the transfer end signal TREND1 to the controller CNT0, and outputs the transfer ready signal TRRDY0 and the transfer end signal TREND0 to the controller CNT1.

The transfer ready signals TRRDY0 and TRRDY1 and the transfer end signals TREND0 and TREND1 are signals indicating the access state of the memory MEM.

The operation control circuit OPC resets the transfer ready signal TRRDY0 (or TRRDY1) to “0” (Busy state) when the memory MEM is accessed by the controller CNT0 (or CNT1) indicating the access state of the memory MEM. The operation control circuit OPC sets the transfer ready signals TRRDY0 and TRRDY1 to “1” (Ready state) when the memory MEM is not accessed. The operation control circuit OPC sets the transfer end signal TREND0 (or TREND1) to “1” for a predetermined clock cycle when data transfer from the controller CNT0 (or CNT1) to the buffer area BUF0 (or BUF1)is completed. The operation control circuit OPC recognizes the completion of the data transfer by a transfer end command supplied from the controllers CNT0 and CNT1 to the memory MEM.

The controller CNT0 (or CNT1) monitors the transfer ready signal TRRDY1 (or TRRDY0) to confirm the ready state of the controller CNT1 (or CNT0), and writes data into the buffer area BUF0 (or BUF1) during the ready state. In addition, the controller CNT0 (or CNT1) monitors the transfer end signal TREND1 (or TREND0) to confirm that the data transfer from the controller CNT1 (or CNT0) to the buffer area BUF1 (or BUF0) is completed, and reads the data from the buffer area BUF1 (or BUF0) after confirming the transfer end.

The eighth embodiment can achieve the same effect as that of the above-mentioned fifth embodiment. In the present embodiment, the controllers CNT0 and CNT1 can confirm the access state (ready state and transfer completion) of the memory MEM without reading the flags TRRDY0, TRRDY1, TREND0, and TREND1. The controllers CNT0 and CNT1 do not 20 need to access the memory MEM to confirm the access state of the memory MEM. Thus, it is possible to reduce the usage frequency of the external buses AD, DT, and CMD0 and CMD1 (the access frequency of the memory MEM). As a result, it is possible to prevent the performance of the memory system MSYS from being deteriorated.

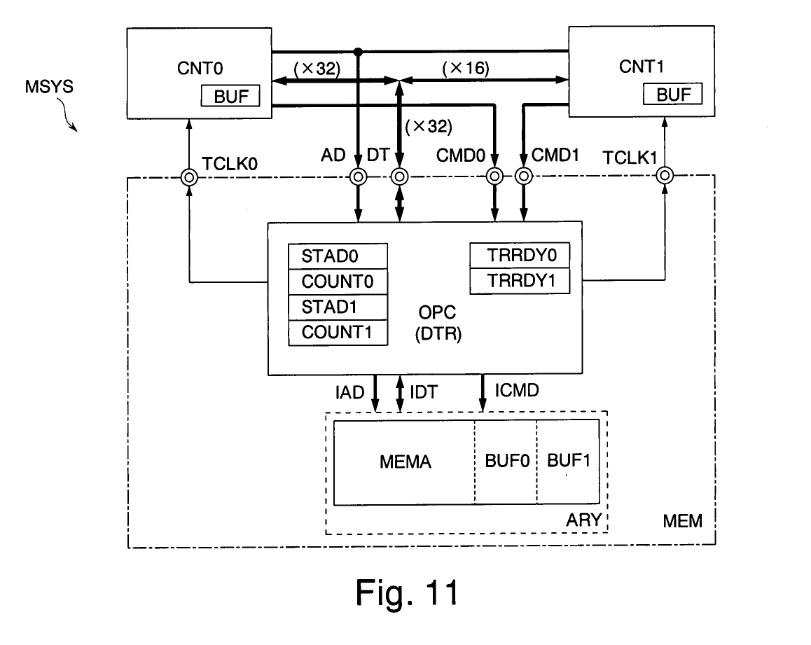

FIG. 11 illustrates a ninth embodiment of the invention. The same elements as those of the fifth embodiment are denoted by the same symbols and a detailed description thereof will thus be omitted herein. In the present embodiment, the operation control circuit OPC (data transfer unit DTU) includes the transfer ready flags TRRDY0 and TRRDY1, start address registers STAD0 and STAD1, and counter registers COUNT0 and COUNT1. In addition, the operation control circuit OPC outputs transfer clocks TCLK0 and TCLK1 (synchronous signals) to the controllers CNT0 and CNT1. Other configuration is the same as that of the fifth embodiment.

In the present embodiment, the operation control circuit OPC has a function of transferring data from the buffer area BUF0 to the controller CNT1, and a function of transferring data from the buffer area BUF1 to the controller CNT0. The transfer ready flags TRRDY0 and TRRDY1, the start address registers STAD0 and STAD1, and the counter registers COUNT0 and COUNT1 are assigned, for example, to the I/O space (memory map I/O).

The start address register STAD0 stores the start address of the buffer area BUF0 that stores data transferred to the controller CNT1. The start address register STAD1 stores the start address of the buffer area BUF1 that stores data transferred to the controller CNT0. The counter register COUNT0 stores the number of data (for example, the number of bytes) transferred from the buffer area BUF0 to the controller CNT1. The counter register COUNT1 stores the number of data transferred from the buffer area BUF1 to the controller CNT0.

The start address register STAD0 and the counter register COUNT0 can be written by the controller CNT0. The start address register STAD1 and the counter register COUNT1 can be written by the controller CNT1.

For example, when data is transferred from the controller CNT0 through the buffer area BUF0 to the controller CNT1, the transferred data is written from the controller CNT0 to the buffer area BUF0, similarly to the fifth embodiment. The controller CNT0 reads the transfer start address and the number of transferred data of the buffer area BUF0 into the start address register STAD0 and the counter register COUNT.

In response to the write operation, the operation control circuit OPC sequentially reads the buffer area BUF0 and outputs data from the data terminal DT in synchronization with the transfer clock TCLK1 during the period when the transfer ready flags TRRDY0 and TRRDY1 are set to “1” (ready state). The operation control circuit OPC generates the transfer clock TCLK1 having the same number of pulses as the number of data stored in the counter register C0UNT. The controller CNT1 receives the data DT in synchronization with the transfer clock TCLK1. That is, the data transfer from the controller CNT0 to the controller CNT1 is carried out through the memory MEM. The data transfer from the controller CNT1 to the controller CNT0 is similarly carried out.

The ninth embodiment can achieve the same effect as that of the above-mentioned fifth embodiment. In the present embodiment, since the transfer clock TCLK0 (or TCLK1) is output in response to the transfer completion of the data DT, the controllers CNT0 and CNT1 can receive the data without accessing the memory MEM. Since the access frequency of the memory MEM is reduced, it is possible to prevent the performance of the memory system MSYS from being deteriorated.

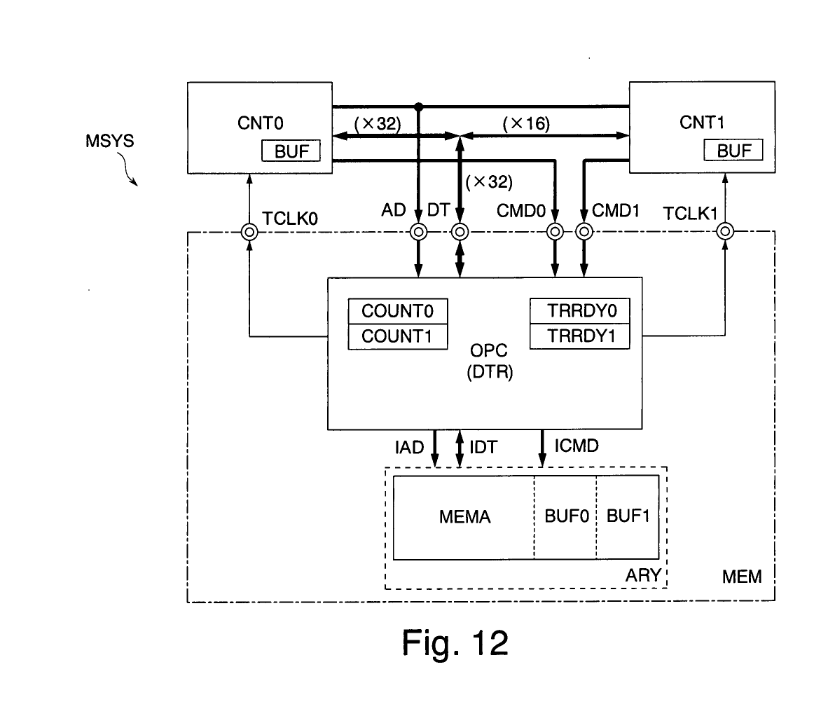

FIG. 12 illustrates a tenth embodiment of the invention. The same elements as those of the fifth and ninth embodiments are denoted by the same symbols and a detailed description thereof will thus be omitted herein. In the present embodiment, the operation control circuit OPC (data transfer unit DTU) has the transfer ready flags TRRDY0 and TRRDY1 and the counter registers COUNT0 and COUNT1 and does not have the start address registers STAD0 and STAD1. 0ther configuration is the same as that of the fifth embodiment.

In the present embodiment, the transfer data is written from the initial addresses of the buffer areas BUFO and BUF1. Thus, the start address registers STADO and STAD1 are not needed. The tenth embodiment can achieve the same effect as that of the above-mentioned fifth and ninth embodiments.

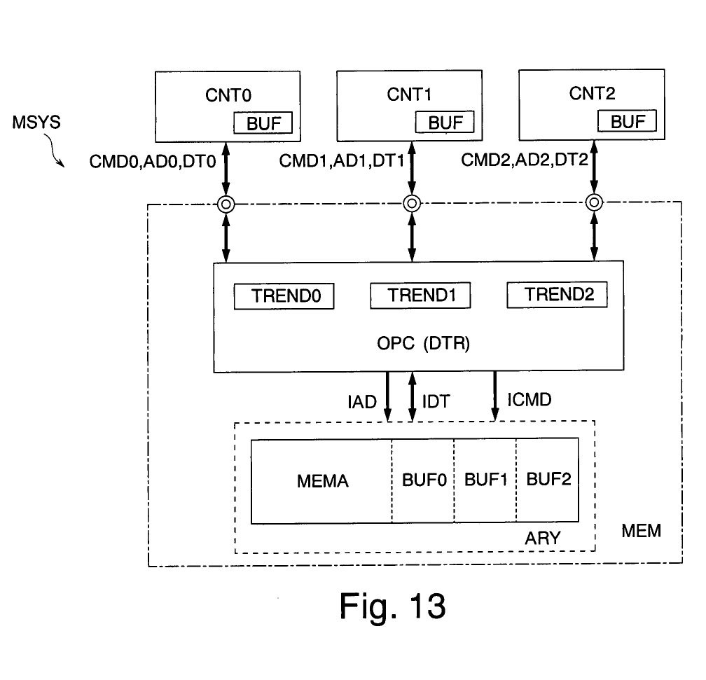

FIG. 13 illustrates an eleventh embodiment of the invention. The same elements as those of the fifth embodiment are denoted by the same symbols and a detailed description thereof will thus omitted herein. In the present embodiment, the semiconductor memory MEM has independent external terminals CMD0, AD0, DT0; CMD1, AD1, DT1; CMD2, AD2, and DT2 to be connected to three controllers CNT0 to CNT2. The operation control circuit OPC (data transfer unit DTU) has transfer end flags TREND0 to TREND2 corresponding to the controllers CNT0 to CNT2. The memory cell array ARY has buffer areas BUF0 to BUF2 corresponding to the controllers CNT0 to CNT2. Other configuration is the same as that of the fifth embodiment.

In the present embodiment, since the external terminals are independent, for example, the controller CNT0 can access the memory MEM without confirming the access states of the other two controllers CNT1 and CNT2. Thus, the transfer ready flag TRRDY of the fifth embodiment is not needed. When access requests of the controllers CNT0 to CNT2 occur in conflict, the access order of the memory cell array ARY is adjusted by the operation control circuit OPC. That is, the operation control circuit OPC has an arbiter function.

For example, when data is transferred from the controller CNT0 to the controller CNT2, the controller CNT0 writes the data into the buffer area BUF0 and sets the transfer end flag TRENDO to “1”. The controller CNT2 confirms that the transfer end flag TREND0 has been set, and reads the data from the buffer area BUF0. That is, the data transfer is executed. At this time, the controllers CNT0 and CNT2 recognize that they transfer the data to each other.

The eleventh embodiment can achieve the same effect as that of the above-mentioned fifth embodiment. In the present embodiment, by forming external terminals (external buses) independent from each other, each of the controllers CNT0 to CNT2 can access the memory MEM and transfer the data without confirming the access states of the other controllers.

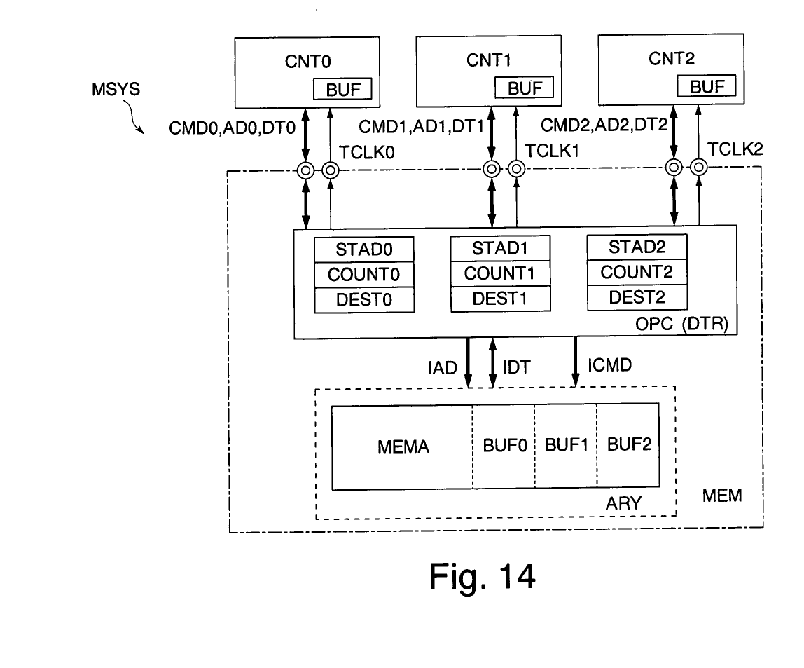

FIG. 14 illustrates a twelfth embodiment of the invention. The same elements as those of the fifth, ninth, and eleventh embodiments are denoted by the same symbols and a detailed description thereof will thus be omitted herein. In the present embodiment, the operation control circuit OPC (data transfer unit DTU) has start address registers STAD0 to STAD2, counter registers COUNT0 to COUNT2, and transfer destination registers DEST0 to DEST2. The start address registers STAD0 to STAD2 and counter registers COUNT0 to COUNT2 have the same functions as those of the ninth embodiment. Similarly to the ninth embodiment, the operation control circuit OPC outputs the transfer clocks TCLK0 to TCLK2 to the controllers CNT0 to CNT2. Other configuration is the same as that of the eleventh embodiment.

The transfer destination registers DEST0 to DEST2 store information indicating transfer destinations of data. For example, each of the transfer destination registers DEST0 to DEST2 contains 3 bits. Lower, middle, and upper bits of each of the transfer destination registers DEST0 to DEST2 represent the controllers CNT0, CNT1, and CNT2, respectively.

For example, when the transfer destination register DEST0 is set to “110” in binary, data written into the buffer area BUF0 is transferred to the controllers CNT1 and CNT2. Thus, the operation control circuit OPC outputs the transfer clocks TCLK1 and TCLK2 together with the data DT1 and DT2. When the transfer destination register DEST1 is set to “110” in binary, data written into the buffer area BUF1 is transferred only to the controller CNT2. Thus, the operation control circuit OPC outputs the transfer clock TCLK2 together with the data DT2.

The twelfth embodiment can achieve the same effect as that of the fifth, ninth, and eleventh embodiments. In the present embodiment, it is possible to transfer data from a single controller CNT through the memory MEM to a plurality of controllers CNT (multicast).

A sub-controller CNT outputting data can be easily recognized by bit values of the transfer destination registers DEST0 to DEST2.

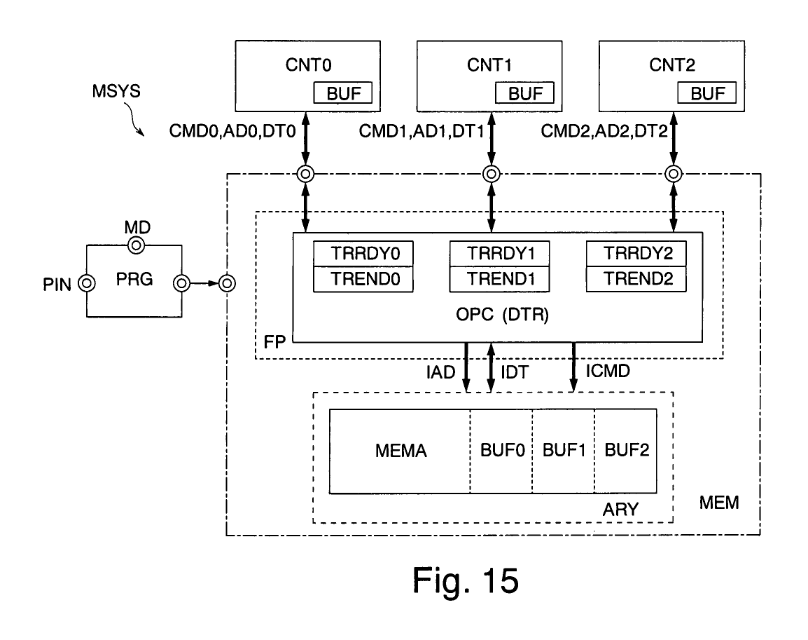

FIG. 15 illustrates a thirteenth embodiment of the invention. The same elements as those of the eleventh embodiment are denoted by the same symbols and a detailed description thereof will thus be omitted herein. In the present embodiment, the operation control circuit OPC (data transfer unit DTU) is formed on the field programmable unit FP. Other configuration is the same as that of the eleventh embodiment. The thirteenth embodiment can achieve the same effect as that of the above-mentioned second and eleventh embodiments.

While the above-mentioned first to fourth embodiments have described cases where the DMAC is activated by only the controller CNTO, the invention is not limited thereto. For example, the DMAC may be activated by the controller CNT1 or the controllers CNT0 and CNT1.

While the above-mentioned first to fourth embodiments have described cases where the semiconductor memory MEM is connected to two controllers CNT0 and CNT1, the invention is not limited thereto. For example, the semiconductor memory MEM may be connected to three or more controllers CNT.

While the above-mentioned second embodiment has described a case where the DMAC is formed on the field programmable unit FP, the invention is not limited thereto. For example, the DMAC of each of the third and fourth embodiments may be formed on the field programmable unit FP. The operation control circuit 0PC according to any of the first to fourth embodiments may be formed on the field programmable unit FP.

Similarly to the first embodiment, in the fifth to tenth embodiments, the controller CNT0 may access the memory MEM as DRAM, and the controller CNT1 may access the memory MEM as NOR-type flash memory (FLASH). In this case, the operation control circuit OPC has a function of converting DRAM interface and FLASH interface into FRAM interface. The eleventh to thirteenth embodiments are the same as the fifth to tenth embodiments.

While the above-mentioned embodiments have described cases where the semiconductor memory MEM is formed of FRAM, the invention is not limited thereto. For example, the semiconductor memory MEM may be formed of other nonvolatile semiconductor memory. Alternatively, the semiconductor memory MEM may be formed of volatile semiconductor memory such as DRAM and SRAM.

The invention is not limited to the above embodiments and various modifications may be made without departing from the spirit and scope of the invention. Any improvement may be made in part or all of the components.

What is claimed is:

1. A semiconductor memory comprising:
a memory cell array having a plurality of sub-arrays; and
a data transfer unit alternately accessing said sub-arrays to transfer data between said sub-arrays.

2. The semiconductor memory according to claim 1, further comprising
a transfer register storing a transfer source address and a transfer destination address of data transferred by said data transfer unit.

3. The semiconductor memory according to claim 1, further comprising
an access right register setting an access right to said sub-arrays for each of controllers connected to the semiconductor memory.

4. The semiconductor memory according to claim 1, further comprising
an access right register setting an access right of said data transfer unit to said sub-arrays.

5. The semiconductor memory according to claim 1, further comprising
external terminals connected to a master controller and at least one sub-controller, wherein
said data transfer unit starts transferring data in response only to a transfer request of said master controller.

6. The semiconductor memory according to claim 1, further comprising:
a field programmable unit in which a logic is programmable; and
a nonvolatile program area storing a program for configuring the logic of said field programmable unit, wherein
said data transfer unit is provided in said field programmable unit.

7. The semiconductor memory according to claim 1, wherein
said data transfer unit is formed as a direct memory access controller.

8. The semiconductor memory according to claim 1, wherein
two of said sub-arrays each have an area for storing data and an area for storing an error correction code of the data, and systems of the error correction codes stored in the two of said sub-arrays are different from each other.

9. The semiconductor memory according to claim 8, further comprising
an error control circuit that generates said error correction code according to a data storage destination and corrects data read from each of the two sub-arrays by using the generated error correction code.

10. The semiconductor memory according to claim 9, wherein
said error control circuit includes a code converting unit that converts an error correction code read from a source sub-array into an error correction code corresponding to a destination sub-array when data is transferred by said data transfer unit from one of said sub-arrays to another one of said sub-arrays.

11. A memory system comprising:
a semiconductor memory having a memory cell array;
a plurality of controllers accessing said semiconductor memory; and
data lines connecting said semiconductor memory and said controllers, wherein
said semiconductor memory includes a data transfer unit which receives data output from one of said controllers and outputs the received data to another one of said controller in order to transfer the data between said controllers through said semiconductor memory.

12. The memory system according to claim 11, wherein
said memory cell array is partitioned into a normal memory area that is accessed by each of said controllers and a buffer area that temporarily stores data received by said data transfer unit.

13. The memory system according to claim 12, wherein
said data transfer unit uses said buffer area when data is transferred between a controller having a relatively large data bit width and a controller having a relatively small data bit width.

14. The memory system according to claim 12, wherein
said data transfer unit uses said buffer area when data is transferred between a controller having a relatively high operating frequency and a controller having a relatively low operating frequency.

15. The memory system according to claim 11, wherein:
one of said controllers is a master controller and the rest thereof are sub-controllers;
said data lines are independently provided for each of said controllers; and
said data transfer unit outputs data received from said master controller to said sub-controllers.

16. The memory system according to claim 15, wherein
said data transfer unit includes a transfer destination register storing transfer destination information sent from said master controller, and outputs data received from said master controller to said sub-controller corresponding to the transfer destination information stored in the transfer destination register.

17. The memory system according to claim 11, wherein
said data transfer unit includes a flag indicating an access state of each of said controllers to said semiconductor memory.

18. The memory system according to claim 11, wherein
said data transfer unit outputs a signal indicating an access state of each of said controllers to said semiconductor memory.

19. The memory system according to claim 11, wherein
said data transfer unit outputs a transfer clock which is a synchronizing signal for outputting the received data to another one of said controllers.

20. The memory system according to claim 11, wherein said semiconductor memory includes:
a field programmable unit in which a logic is programmable; and
a nonvolatile program area storing a program for configuring the logic of said field programmable unit, and wherein
said data transfer unit is provided in said field programmable unit.
